(19) United States
(12) Patent Application Publication
(10) Pub. No.: US 2016/0134237 A1
(43) Pub. Date: May 12, 2016

(54) LOW POWER OSCILLATOR SYSTEM

(71) Applicant: InvenSense, Inc., San Jose, CA (US)

(72) Inventors: Stephen LLOYD, Los Altos, CA (US); Derek SHAEFFER, Redwood City, CA (US)

(21) Appl. No.: 14/538,299

(22) Filed: Nov. 11, 2014

(51) Int. Cl. H03B 5/30

(52) U.S. Cl. CPC H03B 5/30

(57) ABSTRACT

In a first aspect, an oscillator is disclosed. The oscillator comprises a digital circuit; and at least one Microelectromechanical system (MEMS) resonator. The oscillator includes a non-volatile memory, the non-volatile memory (NVM) storing a frequency value related to a resonant frequency of the at least one MEMS resonator. The digital circuit utilizes the frequency value stored in the NVM to provide a measure of real time from the MEMS resonator. In a second aspect, a system is disclosed. The system includes a processor and at least one Microelectromechanical system (MEMS) resonator operating at first frequency. The system also includes a memory. The memory storing a frequency value related to a resonant frequency of the at least one MEMS resonator. The frequency value is measured by an outside source. The processor utilizes the frequency value stored in the memory to provide a measure of real time from the MEMS resonator.

### FIELD OF THE INVENTION

The present invention relates generally to integrated systems arranged to include microelectromechanical systems (MEMS) that provide for signal processing and more particularly to providing an effective low power oscillator for such systems.

### BACKGROUND

Providing accurate clock signals by an integrated sensor system in a cost efficient way often involves adding additional circuitry which significantly increases power consumption of the overall circuitry. Accordingly, what is needed is a device and system that is able to facilitate accurate clock signals to allow for efficient communication among the sensors to be used for data acquisition which is also able to provide processing of the received data to meet user needs in the most cost efficient and as low power manner as possible.

Accordingly, the present invention addresses such a need and solution and is directed to such a need in overcoming the prior limitations in the field.

### SUMMARY

In a first aspect, an oscillator is disclosed. The oscillator comprises a digital circuit; and at least one Microelectromechanical system (MEMS) resonator. The oscillator includes a non-volatile memory, the NVM storing a frequency value related to a resonant frequency of the at least one MEMS resonator. The digital circuit utilizes the frequency value stored in the NVM to provide a measure of real time from the MEMS resonator.

In a second aspect, a system is disclosed. The system includes a processor and at least one Microelectromechanical system (MEMS) resonator operating at a first frequency. The system also includes a memory. The memory storing a frequency value related to a resonant frequency of the at least one MEMS resonator. The frequency value is measured by an outside source. The processor utilizes the frequency value stored in the NVM to provide a measure of real time from the MEMS resonator.

Accordingly, in a system and method in accordance with the present invention a very low power, low cost, oscillator can be provided that is highly accurate timing source with a stable resonator that may be initially slightly inaccurate, such as a MEMS based resonator.

### BRIEF DESCRIPTION OF THE DRAWINGS

FIG. 1 is a block diagram of an oscillator circuit in accordance with an embodiment.

FIG. 2A is an exemplary integrated sensor system (ISS) of the present invention having one or more embedded sensors in one or more MEMS chips and one or more CMOS chips with electronic circuits, in a single chip, in accordance with one or more embodiments of the present invention.

FIG. 2B is an exemplary integrated sensor system (ISS) of the present invention having one or more MEMS chips and one or more CMOS chips vertically stacked and bonded on a substrate, in accordance with one or more embodiments of the present invention.

FIG. 2C is an exemplary integrated sensor system (ISS) of the present invention having one or more MEMS chips and one or more CMOS chips vertically stacked and bonded on a substrate, in accordance with one or more embodiments of the present invention

FIG. 3 depicts a system diagram of the ISS in which the sensor hub comprises one or more analog to digital convertors, one or more processors, memory, a power management block and a controller block, in accordance with one or more embodiments of the present invention.

FIG. 4 is a block diagram of a system that provides multiple timing sources within a device.

### DETAILED DESCRIPTION

This present invention relates generally to integrated systems arranged to include microelectromechanical systems (MEMS) that provide for signal processing and more particularly to providing an effective low power oscillator for such systems. The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiments shown, but is to be accorded the widest scope consistent with the principles and features described herein.

In an embodiment in accordance with the present invention frequency of a stable MEMS oscillator is accurately measured either at a single temperature or across a temperature range. The system uses the information on the exact frequency of the clock provided by the MEMS oscillator to map any timing or sampling to real time intervals. Thereafter accurate time stamps can be generated using the clock with an arbitrary yet stable frequency.

Accordingly in a system and method in accordance with the present invention a very low power, low cost, oscillator can be provided that is highly accurate timing source with a stable resonator that may be initially slightly inaccurate, such as a MEMS based resonator. To describe the features of the present invention in more detail refer now to the following discussion in conjunction with the accompanying figures.

In the described embodiments, Micro-Electro-Mechanical Systems (MEMS) refers to a class of devices fabricated using semiconductor-like processes and exhibiting mechanical characteristics such as the ability to move or deform. MEMS often, but not always, interact with electrical signals. Silicon wafers containing MEMS structures are referred to as MEMS wafers. MEMS device may refer to a semiconductor device implemented as a micro-electro-mechanical system. A MEMS device includes mechanical elements and optionally includes electronics for sensing. MEMS devices include but not limited to gyroscopes, accelerometers, magnetometers, and pressure sensors. MEMS features refer to elements formed by MEMS fabrication process such as bump stop, damping hole, via, port, plate, proof mass, standoff, spring, seal ring, proof mass. MEMS structure may refer to any feature that may be part of a larger MEMS device.

One or more MEMS feature comprising moveable elements on a MEMS structure. Integrated Circuit (IC) substrate may refer to a silicon substrate with electrical circuits, typically CMOS circuits. A chip includes at least one substrate typically formed from a semiconductor material. A single chip may be formed from multiple substrates, where the substrates are mechanically bonded to preserve the functionality. Multiple chip includes at least 2 substrates, wherein the 2 substrates are electrically connected, but do not require mechanical bonding. A package provides electrical connection between the bond pads on the chip to a metal lead that can be soldered to a PCB. A package typically comprises a substrate and a cover.

In the described embodiments, “raw data” or “sensor data” refers to measurement outputs from the sensors which are not yet processed. “Motion data” refers to processed sensor data. Processing may include applying a sensor fusion algorithm or applying any other algorithm such as determining context, gestures, orientation, or confidence value. In the case of the sensor fusion algorithm, data from one or more sensors are combined to provide an orientation of the device. Processor data for example may include motion data plus audio data plus vision data (video, still frame) plus touch/temp data plus smell/taste data.

As used herein, integrated sensor systems (ISSs) comprise microelectromechanical systems (MEMS) and sensor subsystems for a user's application which combine multiple sensor sensing types and capabilities (position, force, pressure, discrete switching, acceleration, angular rate, level, etc.), where that application may be biological, chemical, electronic, medical, scientific and/or other sensing application. ISSs as used herein also are intended to provide improved sizing and physical structures which are oriented to become smaller with improved technological gains. Similarly, as used here, ISSs also have suitable biocompatibility, corrosion resistance, and electronic integration for applications in which they may be deployed.

In an embodiment of the invention, the first substrate is attached to the second substrate through wafer bonding, as described in commonly owned U.S. Pat. No. 7,104,129 (incorporated herein by reference) that simultaneously provides electrical connections and hermetically seals the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

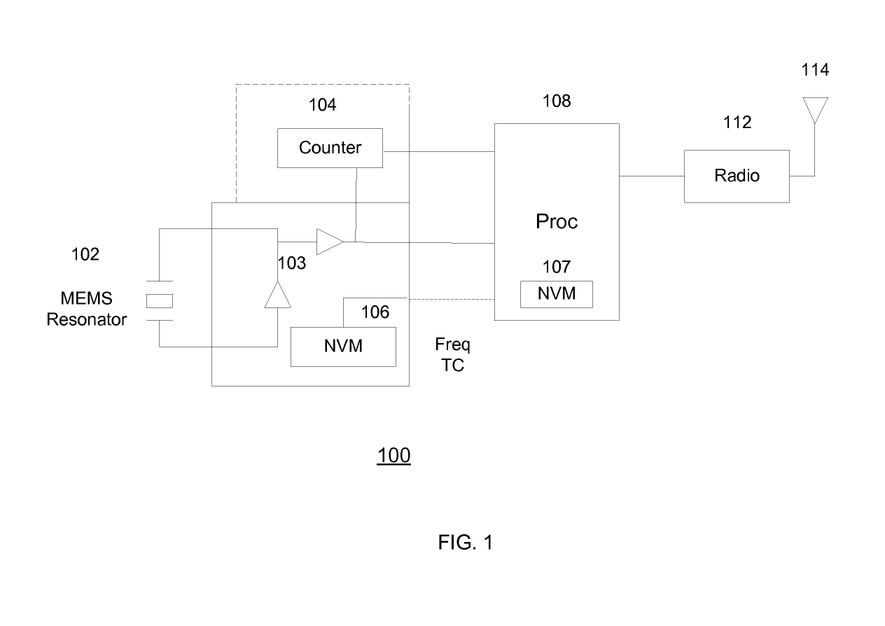

FIG. 1 is a block diagram of an oscillator circuit 100 in accordance with an embodiment. The oscillator circuit 100 includes a MEMS resonator 102 coupled to an amplifier 103. The amplifier 103 is coupled to a digital circuit such as a processor 108. The processor 108 is coupled to a nonvolatile memory (NVM) 106. The processor 108 is also coupled to a radio 112 which is coupled to an antenna 114. A key feature of the present invention is that the MEMS resonator 102 is by itself only able to be accurate within 10% of a particular frequency. On the other hand a digital circuit, such as the processor 108 can ensure that frequency of the MEMS resonator 102 is accurate up to 10 ppm. Therefore initially, for example the resonant frequency of the MEMS resonator 102 over a temperature range is stored in the NVM 106 during for example production testing of the resonator 102. Thereafter the processor 108 can be utilized to ensure that that the resonator 102 remains at that frequency up to 10 ppm accuracy. In so doing, additional circuitry such as a phase locked loop (PLL) or the like is unnecessary for the operation of the system 100.

The count provided by the counter 104 can be utilized as an interrupt to the processor 108. In so doing when the processor 108 wakes up due to the interrupt signal from the counter the processor 108 can determine if the count is too high or low and either speed up the resonator 102 or slow it down to maintain the proper frequency. The radio 112 allows the processor 108 to obtain an accurate clock from an external source such as the Internet to determine if there is an error in timing of the resonator 102. This information can be stored in the NVM 107 of the processor 108 to also provide a more accurate clock.

The circuit 100 may be part of a sensor platform include a sensor sensing devices, electronic circuits for converting analog signals to digital signals, and is capable of determining sensed activities and information. These activities for example could include but are not limited to sleeping, waking up, walking, running, biking, participating in a sport, walking on stairs, driving, flying, training, exercising cooking, watching a television, reading, working at a computer, and eating.

Furthermore, the sensors could be utilized for determining sensed locations. For example, these locations include but are not limited to a home, a workplace, a moving vehicle, indoor, outdoor, a meeting room, a store, a mall, a kitchen, a living room, and bedroom.

In such an embodiment signals from a global positioning system (GPS) or other wireless system that generates location data could be utilized. In addition the sensors could send data to a GPS or other wireless system that generates location data to aid in low power location and navigation.

Sensors may include those devices which are capable of gathering data and/or information involving measurements concerning an accelerometer, gyroscope, compass, pressure, microphone, humidity, temperature, gas, chemical, ambient light, proximity, touch, and tactile information, for example; however the present invention is not so limited. Sensors of the present invention are embedded sensors for those sensors on the chip and/or external to the ISS for sensed data external to the chip, in one or more embodiments.

In another embodiment, the sensors are a MEMS sensor or a solid state sensor, though the sensors of the device and system may be any type of sensor. For instance, it is envisioned that the present invention may use data sensed from sensors including but not limited to a 3-axis accelerometer, 3-axis gyroscope, 3-axis magnetometer, pressure sensor, microphone, chemical sensor, gas sensor, humidity sensor, image sensor, ambient light, proximity, touch, and audio sensors, etc.

In a further embodiment, a gyroscope of the present invention includes the gyroscope disclosed and described in commonly-owned U.S. Pat. No. 6,892,575, entitled “X-Y Axis Dual-Mass Tuning Fork Gyroscope with Vertically Integrated Electronics and Wafer-Scale Hermetic Packaging”, which is incorporated herein by reference. In another embodiment, the gyroscope of the present invention is a gyroscope disclosed and described in the commonly-owned U.S. patent application Ser. No. 13/235,296, entitled “Micromachined Gyroscope Including a Guided Mass System”, also incorporated herein by reference. In yet a further embodiment, the pressure sensor of the present invention is a pressure sensor as disclosed and described in the commonly-owned U.S. patent application Ser. No. 13/536,798, entitled “Hermetically Sealed MEMS Device with a Portion Exposed to the Environment with Vertically Integrated Electronics,” incorporated herein by reference.

In a further embodiment of the present invention includes the sensors are formed on a MEMS substrate, the electronic circuits are formed on a CMOS substrate, the CMOS and the MEMS substrates are vertically stacked and attached is disclosed and described in commonly-owned U.S. Pat. No. 8,250,921, entitled “Integrated Motion Processing Unit (MPU) With MEMS Inertial Sensing And Embedded Digital Electronics”.

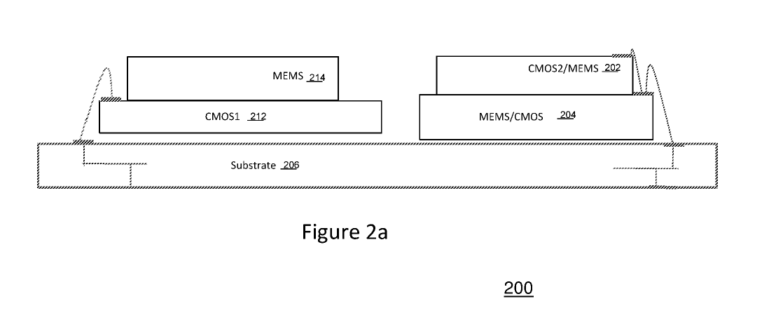

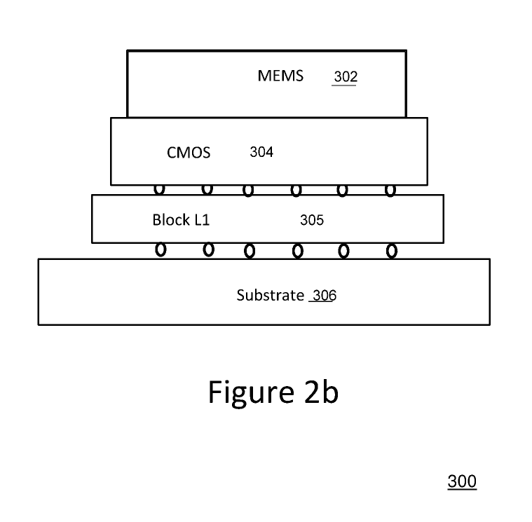

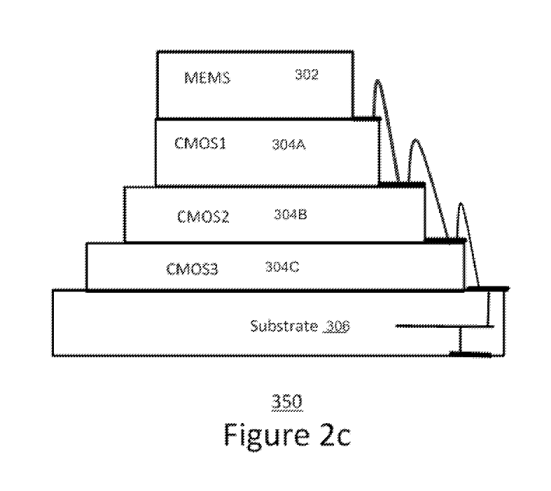

FIG. 2A is an exemplary integrated sensor system (ISS) of the present invention having one or more embedded sensors in one or more MEMS chip 214 and one or more CMOS chip 212 with electronic circuits, attached to a substrate 206 to form a single chip 200, in accordance with one or more embodiments of the present invention. In the described embodiments, the electronic circuits may include circuitry for sensing signals from sensors, processing the sensed signals and converting to digital signals.

In an embodiment, FIG. 2A also provides for an ISS of the present invention having a first arrangement of a MEMS 214 arranged with a CMOS 212 vertically, and a second arrangement of a chip 202 vertically stacked with a chip 204, where the first and second arrangement are side-by-side on a substrate 206. Chip 202 and chip 204 can be any combination of CMOS and MEMS. In another embodiment, chip 202 may not be present. Yet, in another embodiment, multiple chips such as 202 or 204 may be stacked. In some embodiments, CMOS chip may also include memory.

FIG. 2B is an exemplary integrated sensor system (ISS) 300 of the present invention having one or more MEMS chip 302 and one or more CMOS chip 304 vertically stacked and bonded on a substrate 306, in accordance with one or more embodiments of the present invention. In an arrangement, the combined MEMS and CMOS chips are bonded or connected by solder balls to block 305 and then bonded to the substrate 306. In an embodiment block 305 could be any of or any combination of electronics, sensors, CMOS IC, IPD (Integrated Passive Device), or solid state devices such as batteries.

FIG. 2C is an exemplary integrated sensor system (ISS) 350 of the present invention having one MEMS chip 302 and a plurality of CMOS chips 304A-304C are vertically stacked and CMOS chip 304A is wire bonded to CMOS chip 304B which is wire bonded to CMOS chip 304C. The CMOS chip 304C in turn is wire bonded to a substrate 306, in accordance with one or more embodiments of the present invention. In an embodiment the CMOS chips 304A, 304B and 304C could contain any of or any combination of electronic circuits.

In one embodiment, this present invention relates to integrated systems arranged to include microelectromechanical systems (MEMS) that provide for signal processing and more particularly for those systems that provide for the processing of signals from sensors and also provide for the outputting of information from the processed signals to other devices, applications and arrangements. Further, the application relates to integrated sensor systems (ISSs) comprising one or more embedded sensors and a sensor hub arranged on a single chip, which can also receive inputs from external sensor sources and provide for facilitating efficient communication among the sensors for improved high-level features, such as interpreting gestures or actions according to the context.

The present invention provides for an ISS implemented in a single chip that can be mounted onto a surface of a printed circuit board (PCB). In another embodiment, the ISS of the present invention comprises one or more MEMS chip having one or more sensors attached to one or more CMOS chips with electronic circuitry. In a further embodiment, one or more MEMS chips and one or more CMOS chips are vertically stacked and bonded. In yet another embodiment, an ISS of the present invention provides for having more than one MEMS and more than one CMOS chips arranged and placed side-by-side.

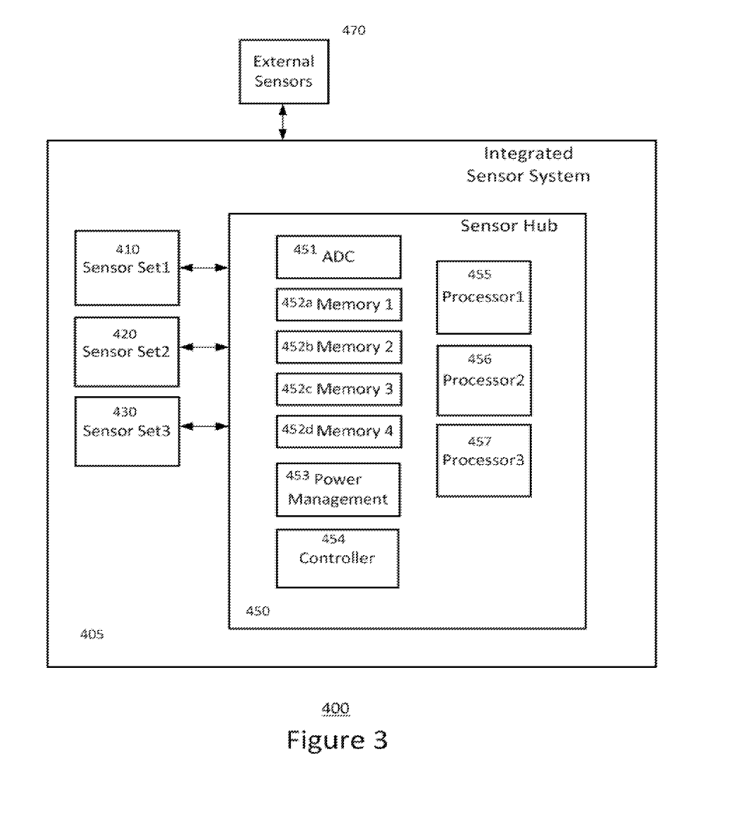

FIG. 3 depicts a system diagram 400 of the ISS 405 in which the sensor hub 450 comprises one or more analog to digital convertors 451, one or more processors (455-457), memory 452a-452d, a power management block 453 and a controller block 454, in accordance with one or more embodiments of the present invention. In an embodiment, the sensor hub 450 comprises one or more analog to digital convertors, one or more processors, memory, one or more power management blocks and one or more controller blocks. For example, the one or more processors 455-457 include but are not limited to any and any combination of an audio processor, an image processor, a motion processor, a touch processor, a location processor, a wireless processor, a radio processor, a graphics processor, a power management processor, an environmental processor, an application processor (AP), and a microcontroller unit (MCU).

Any of the one or more processors 455-457 or external sensors 470 can provide one or more interrupts to an external device, any of the embedded or external sensors, or any processor or the like based upon the sensor inputs. The interrupt signal can perform any of or any combination of wake-up a processor and/or a sensor from a sleep state, initiate transaction between memory and sensor, initiate transaction between memory and processor, initiate transfer of data between memory and external device. In addition, the sensor hub may include in some embodiments a real-time clock (RTC), a system clock oscillator or any other type of clock circuitry. In an embodiment, resonators for the clocks can be implemented with MEM structure. In so doing external crystal resonators are not required thereby saving cost, reducing power requirements and reducing the overall size of the device. To describe the use of the MEMS resonator in accordance with the present invention in this kind of environment refer now to the following description in conjunction with the accompanying drawings.

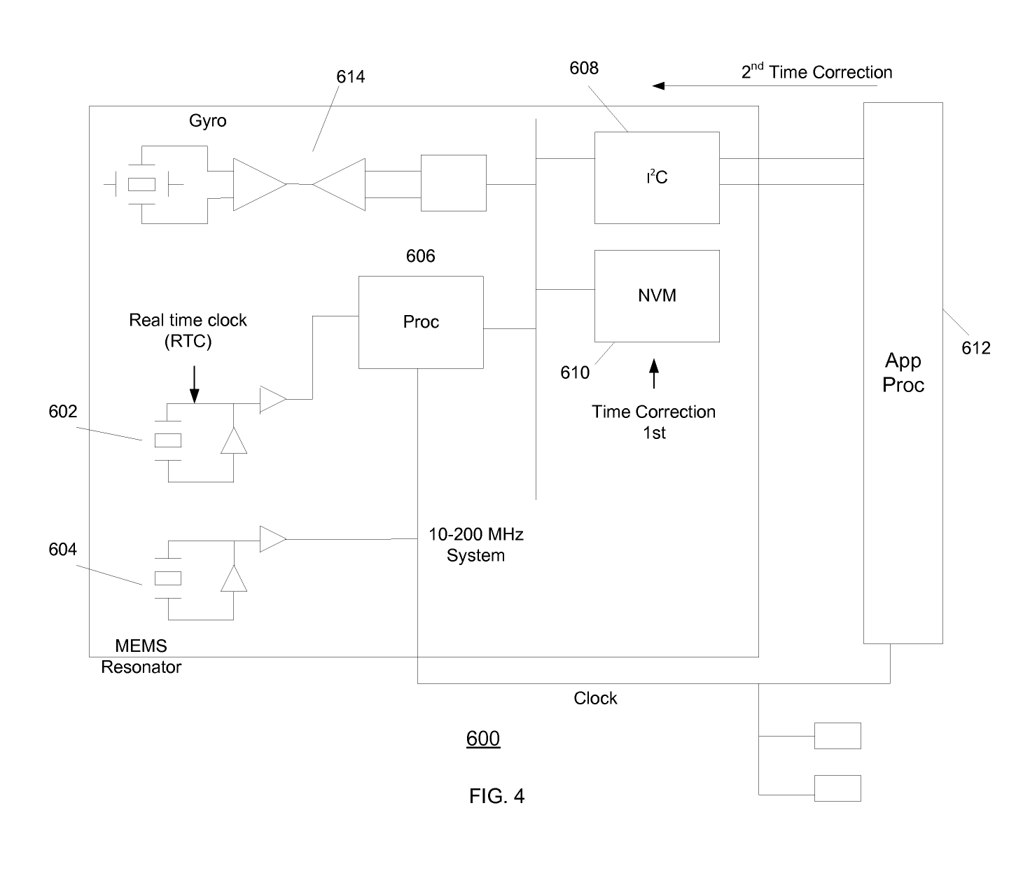

FIG. 4 is a block diagram of a system 600 that provides multiple timing sources within a device. This system could be for example a smart device. FIG. 4 has elements that are similar to FIG. 1 but includes two MEMS resonators 602 and 604. The MEMS resonator 602 in a embodiment acts a real time clock (RTC) and operates at low frequency, for example 32 kHz, and the MEMS resonator 604 acts as a system clock and operates at a higher frequency, for example 10-200 MHz. The system 600 also includes a MEMS sensor 614 such as a gyroscope. One of ordinary skill in the art readily recognizes that there could be multiple and different types of sensors and that would be within the spirit and scope of the present invention.

MEMS resonators 602 and 604 are coupled to the processor 606. The MEMS resonator 604 is also coupled to an application processor 612 which may have a connection to another network such as the Internet. A memory such as a NVM 610 is coupled via a bus to the processor 606 to provide an initial time correction to the system 600. An I²C channel 608 receives information from the application processor 612 which can provide a second more accurate time correction from an outside source for example a second clock signal from for example the Internet or another system to provide additional frequency corrections. The another system can be for example a second processor (not shown). In so doing the system 600 will have improved accuracy over conventional systems.

In this embodiment, the frequency of the MEMS resonators 602 and 604 will be measured at the same time the product 600 sensor is production tested, either at a single temperature or across a temperature range and stored in the NVM 610. In this manner, a highly stable low power RTC and a low power system clock can be included in the part with a very small incremental cost addition.

With the absolute frequency stored, systems which require an exact clock frequency can still use the MEMS oscillator as a low noise reference, but also use the stored frequency value to program to determine an exact frequency needed. This is a lower cost option than an external crystal oscillator.

### Advantages

A system and method in accordance with an embodiment, removes the need to “trim” the resonator to an exact frequency. Therefore, a MEMS resonator which has a large variation in initial tolerance can be utilized as an accurate clock and can be very stable over time. There is no need for additional circuitry which adds cost and increases power consumption to maintain the frequency of the MEMs resonator. A system and method in accordance with an embodiment can be used for both low frequency RTC oscillators for very low power or higher frequency system clocks. A system and method in accordance with an embodiment can also be used where resonant MEMS structures such as gyroscopes are also used to generate the system clock to improve accuracy. In a further embodiment, the frequency can also be measured across multiple temperatures to provide a temperature compensated MEMS resonator.

Embodiments of the sensor circuit or system described herein can take the form of an entirely hardware implementation, an entirely software implementation, or an implementation containing both hardware and software elements. Embodiments may be implemented in software, which includes, but is not limited to, application software, firmware, resident software, microcode, etc.

The steps described herein may be implemented using any suitable controller or processor, and software application, which may be stored on any suitable storage location or computer-readable medium. The software application provides instructions that enable the processor to cause the receiver to perform the functions described herein.

Furthermore, embodiments may take the form of a computer program product accessible from a computer-usable or computer-readable medium providing program code for use by or in connection with a computer or any instruction execution system. For the purposes of this description, a computer-usable or computer-readable medium can be any apparatus that can contain, store, communicate, propagate, or transport the program for use by or in connection with the instruction execution system, apparatus, or device.

The medium may be an electronic, magnetic, optical, electromagnetic, infrared, semiconductor system (or apparatus or device), or a propagation medium. Examples of a computer-readable medium include a semiconductor or solid state memory, magnetic tape, a removable computer diskette, a random access memory (RAM), a read-only memory (ROM), a rigid magnetic disk, and an optical disk. Current examples of optical disks include DVD, compact disk-read-only memory (CD-ROM), and compact disk-read/write (CD-R/W).

A sensor set as used herein may include a single sensor or be an arrangement of a plurality of sensors, none of which are required to be of the same or similar type or utility and none of which are required to not be of a same or similar type and utility. A sensor set, or grouping, may include or be determined in relation to one or more of the type of sensors, the type of application intended, the type of application the sensor is to be connected or in communication with, etc. It will be appreciated by those skilled in the art that the present invention is not constrained or limited to a particular arrangement of sensor in a specific manner to constitute a grouping herein.

In yet a further embodiment, each of the sets of sensors is connected to a dedicated processor, where the connected processor is a specialized processor, such as that required, by example, for an audio processor to process audio input. In still another embodiment, each of the sets of sensors is arranged in relation to the processor to which it connects.

It will also be appreciated that each of the processors of the present invention can execute various sensor fusion algorithms in which the sensor fusion algorithms are algorithms that combine various sensor inputs to generate one or more of the orientation of the device or combined sensors data that may then be used for further processing or any other actions as appropriate such as determining orientation of the user.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. An oscillator comprising:
a digital circuit;
at least one Microelectromechanical system (MEMS) resonator; and
a non-volatile memory (NVM), the NVM storing a frequency value related to a resonant frequency of the at least one MEMS resonator; wherein the digital circuit utilizes the frequency value stored in the NVM to provide a measure of real time from the MEMS resonator.

2. The oscillator of claim 1, wherein one or more sensors are integrated with the oscillator

3. The oscillator of claim 1 further includes a connection to a network.

4. The oscillator of claim 1 further includes a second MEMS resonator coupled to the processor.

5. The oscillator of claim 4, wherein the at least one MEMS resonator provides a real time clock (RTC) and the second MEMS resonator provides a system clock.

6. The oscillator of claim 1 further includes an interrupt to the digital circuit.

7. The oscillator of claim 1, wherein the digital circuit, the at least one MEMS resonator and the NVM are on a single chip.

8. The oscillator of claim 1, wherein the frequency value is measured across a temperature range.

9. The oscillator of claim 1, wherein the digital circuit comprises a processor.

10. The oscillator of claim 9, wherein the processor comprises a digital signal processor.

11. The oscillator of claim 1 further includes a I²C/SPI channel coupled to an application processor and the digital circuit.

12. The oscillator of claim 1 includes a radio coupled to the digital circuit; wherein the radio allows the digital circuit to obtain an accurate clock from an external source.

13. The oscillator of claim 1 includes a counter coupled between the MEMS resonator and the digital circuit to maintain an accurate frequency.

14. The oscillator of claim 1 includes a communication interface coupled to a network.

15. The oscillator of claim 1, wherein the frequency value comprises an initial frequency value.

16. The oscillator of claim 1, wherein the oscillator is part of a sensor platform.

17. A system comprising:
a processor;
at least one Microelectromechanical system (MEMS) resonator operating at first frequency; and
a memory, the memory storing a frequency value related to a resonant frequency of the at least one MEMS resonator; wherein the frequency value is measured by an external source; wherein the processor utilizes the frequency value stored in the memory to provide a measure of real time from the MEMS resonator.

18. The system of claim 17, wherein the external source comprises any of a network and another system.

19. The system of claim 18, wherein one or more sensors are integrated with the system.

20. The system of claim 18, wherein the network is utilized to add additional frequency corrections.

21. The system of claim 17, wherein the system includes a connection to a network.

22. The system of claim 17, wherein the at least one MEMS resonator comprises first and second MEMS resonators.

23. The system of claim 22, wherein the first MEMS resonator provides a real time clock (RTC) and the second MEMS resonator provides a system clock.

24. The system of claim 17 includes a counter for providing an interrupt to the processor.

25. The system of claim 17, wherein the processor, the at least one MEMS resonator and the memory are on a single chip.

26. The system of claim 17, wherein the frequency value is measured across a temperature range.

27. The system of claim 17, wherein the processor comprises a digital signal processor (DSP).

28. The system of claim 17 includes an I²C/SPI channel coupled to the processor and an application processor.

29. The system of claim 17 includes a radio coupled to the digital circuit; wherein the radio allows the digital circuit to obtain an accurate clock from an external source.

30. The system of claim 17 includes a counter coupled between the at least one MEMS resonator and the digital circuit. The system of claim 17 includes a communication interface to a network.

32. The system of claim 17, wherein the at least one MEMS resonator provides a real time clock (RTC).

33. The system of claim 17, wherein the frequency value comprises an initial frequency value. The system of claim 17, wherein the system is part of a sensor platform.

35. The system of claim 31, wherein the network is utilized to provide additional frequency corrections.

36. The system of claim 17, wherein a second processor or system is utilized to provide additional frequency corrections.
